(19) United States
(12) Patent Application Publication
(10) Pub. No.: US 2024/0053084 A1
(43) Pub. Date: Feb. 15, 2024

(54) TEMPERATURE CONTROL MODULE AND DELIVERY BOX CABINET

(71) Applicant: Dometic Sweden AB, Solna (SE)

(72) Inventors: Peng Wang, Zhuhai (CN); Philip Bridge, Hägersten (SE); Mikael Thelin, Huddinge (SE)

(21) Appl. No.: 18/264,689

(22) PCT Filed: Dec. 29, 2021
(86) PCT No.: PCT/EP2021/087798

§ 371 Date: Aug. 8, 2023

(30) Foreign Application Priority Data
Feb. 9, 2021 (CN) 202110224812.4

(51) Int. Cl. F25D 11/02; F25D 17/04; F25D 29/00

(52) U.S. Cl. CPC F25D 11/027; F25D 17/045; F25D 29/00; F25D 2317/041

(57) ABSTRACT

The present invention refers to a temperature control module for a delivery box cabinet. According to the present invention, the various components of the temperature control module are provided in a compact block-like manner. The temperature control module is formed self-contained such that it can be installed in a modular manner as a temperature control module in the delivery box cabinet besides delivery compartments of the delivery box cabinet. Thus, a quite efficient but still compact overall configuration can be achieved. Furthermore, the present invention refers to a delivery box cabinet provided with such a temperature control module or at least being provided to be supplemented by such a temperature control module.

### CLAIM TO PRIORITY

This 35 U.S.C. § 371 National Stage patent application claims priority to and benefit of PCT Patent Application No. PCT/EP2021/087798, filed Dec. 29, 2021, which claims priority to CN 202110224812.4 filed Feb. 9, 2021, all of which is incorporated by reference herein.

### BACKGROUND

The present embodiments relate to a temperature control module for a delivery box cabinet and to a delivery box cabinet for receiving and storing deliveries like mailings and food deliveries.

In recent years, not only the quantity of delivered non-perishable goods such as mailings has increased, but also the quantity of delivered perishable goods, in particular such as food. This includes not only prepared dishes delivered by a delivery service, but especially also deliveries of whole purchases of non-processed food from corresponding merchants.

When delivered by the delivery service, such deliveries may arrive at the customer's premises at a time when the customer cannot receive them in person. Such a situation may occur when the customer is not at home, for example when the customer is at work. This can further be the case when the customer is busy and may not receive the delivery in person or does not even notice the arrival of the delivery at all, for example if he works in the cellar or garden, for example.

This circumstance is probably impractical for deliveries of non-perishable goods, but in general it is not a major problem there. However, this circumstance is particularly problematic in the case of deliveries of perishable goods, especially of such goods that spoil quickly without proper cooling. Such goods should be cooled constantly in order to guarantee the shelf life of the goods. If the perishable goods are stored by the supplier until they are picked up by the customer or if the perishable goods are deposited at another deposit place until the customer picks them up, such cooling cannot always be guaranteed. Moreover, if the delivered goods are deposited at a deposit place agreed upon with the customer, the safety against theft of the respective goods cannot always be guaranteed.

This task is solved by the delivery box cabinet as described below having two distinct delivery compartments and a temperature control module for controlling the temperature in at least one of these delivery compartments. However, as such delivery box cabinets are not yet known, suitable temperature control modules are not yet known as well.

Thus, it is one object of the present embodiments to provide a suitable and highly functional temperature control module for such a delivery box cabinet. Besides, it is the object of the present embodiments to provide a delivery box cabinet benefiting from the advantages obtained by such a temperature control module.

These tasks are solved with a temperature control module as well as a delivery box cabinet according to the independent claims. Further advantageous improvements for such devices are presented in the dependent claims.

### SUMMARY

According to some embodiments, a temperature control module for a delivery box cabinet comprises an absorption cooling circuit having a compressor, a condenser and an evaporator, and a controller for controlling the operation of the temperature control module. The temperature control module in particular is configured to control the temperature within at least one delivery compartment of the delivery box cabinet. The various components of the temperature control module are provided in a compact block-like manner. In other words, the components of the temperature control module are combined to end up in a box-like overall configuration. The temperature control module is formed self-contained such that it can be installed in a modular manner as a temperature control module in a delivery box cabinet besides the delivery compartments of the delivery box cabinet.

In the scope of the present disclosure, the term “control” has to be understood in the sense of “regulate”. Thus, the temperature control module is configured to influence the temperature within a specific compartment in an active manner. Such a configuration for a temperature control module results in a compact overall configuration of the temperature control module. Moreover, such a configuration for a temperature control module allows to supplement an already provided delivery box cabinet with such a temperature control module in an easy manner. This enables a regulation of the temperature within at least one of the delivery compartments of the delivery box cabinet.

The temperature control module further comprises a condenser fan unit configured to generate a first air flow at the condenser. The temperature control module also comprises an evaporator fan unit configured to generate a second air flow at the evaporator. The fan units enhance the temperature exchange capacity at the condenser and at the evaporator, respectively, resulting in a high efficiency for the temperature control module while having a compact overall configuration.

Further, the temperature control module comprises an air flow guiding configuration configured to separate the first air flow from the second air flow and to guide at least one of the first air flow and the second air flow. Such a configuration allows to increase the efficiency of the temperature control module further.

Further, the air flow guiding configuration defines an inlet air flow path directed to the evaporator and an outlet air flow path directed from the evaporator. The air flow guiding configuration comprises a coupling unit configured to be coupled to an air flow guiding arrangement of the delivery box cabinet. Thus, the temperature control module can be coupled to the remaining components of the delivery box cabinet to serve as a cooling unit resulting in a final implementation of the present embodiments.

Further, the temperature control module is configured such that it can be supplemented by a purification unit configured to purify air within the air flow guiding configuration. Thus, in particular the air from the inner of the delivery box cabinet can be purified while passing the temperature control module for temperature exchange. At the same time, no further space is required outside the temperature control module for providing such a purification unit.

The temperature control module comprises a purification unit configured to purify air within the air flow guiding configuration and a purification control unit for controlling the operation of the purification unit. In particular the purification control unit is configured to operate the purification unit in accordance with a predetermined operation schedule stored within the purification control unit. This configuration enables a specifically adapted operation of the purification unit increasing the efficiency thereof.

The temperature control module comprises an insulation configuration for thermally separating the various components of the temperature control module from each other and/or from the environment of the temperature control module. The insulation configuration increases the efficiency of the temperature control module and/or shields the temperature control module from external thermal influences.

The temperature control module is provided to be used as cooling unit for at least one delivery compartment of the delivery box cabinet. Such a configuration is highly functional.

According to another aspect, a delivery box cabinet for receiving and storing deliveries comprises at least one delivery compartment configured to receive and store deliveries. The delivery box cabinet further comprises a temperature control module receiving configuration. The temperature control module receiving configuration is configured such that at least one of the above described temperature control modules can be removably provided in the temperature control module receiving configuration. The temperature control module can be operatively coupled to the other components of the delivery box cabinet via the temperature regulation module receiving configuration. Such a delivery box cabinet can be supplemented with one of the above described temperature control modules allowing to transfer the technical effects obtained therewith to the delivery box cabinet in an easy manner.

Further, the delivery box cabinet comprises an air flow guiding arrangement defining at least one air flow path from at least one air flow guiding coupling unit to the inside of at least one delivery compartment of the delivery box cabinet or vice versa. The air flow guiding coupling unit is configured to be coupled to a coupling unit of a temperature control module provided in and coupled to the temperature control module receiving configuration of the delivery box module. Such a configuration allows to reliably guide the generated air flows within the delivery box cabinet in a desired manner, thus, resulting in the desired temperature regulation by the temperature control module for the other components of the delivery box cabinet.

Further, the air flow guiding arrangement is configured to define several separate air flow guides between the temperature control module, which is provided in and coupled to the temperature control module receiving configuration, and various sections of at least one of the delivery compartments and/or of various separate delivery compartments of the delivery box cabinet. This allows to define various different temperature zones within the delivery compartments of the delivery box cabinet. Thus, the function of the delivery box cabinet can be adapted to the specific demands or wishes of a user in a highly flexible manner.

The delivery box cabinet comprises at least one locking unit configured to lock at least one of the delivery compartments of the delivery box cabinet. In particular each delivery compartment comprises at least one individual locking unit. Such locking units allow to implement a suitable theft protection for the deliveries stored within the corresponding delivery compartments.

The delivery box cabinet comprises a communication and control unit. The communication and control unit is configured to exchange information data with at least some of the various components of the delivery box cabinet and/or an external device. Furthermore, the communication and control unit is configured to control at least some the various components of the delivery box cabinet. Thus, an optimized operation of the overall delivery box cabinet and in particular of the various components of the delivery box cabinet can be achieved.

Further, the communication and control unit is configured to be coupled to a controller of a temperature control module provided in and coupled to the temperature control module receiving configuration. The communication and control unit is further configured to communicate with said controller. In particular the communication and control unit is also configured to be coupled wirelessly to an external device. Thus, the operation of the temperature control module can be controlled and in particular can be based on data received from said external device.

Further, the communication and control unit is configured to be coupled further to at least one locking unit of the delivery box cabinet as well as to a purification unit of a temperature control module. The communication and control unit is configured to receive information data about a locking state of said locking unit(s) and to process the information data. Furthermore, the communication and control unit is configured to control the operation of the purification unit based on said processed information data. Thus, the purification unit can be operated in specific situations only, for example in a state, in which the locking units are in the locked state such that the delivery compartments are closed.

The delivery box cabinet comprises any one of the above described temperature control modules provided in and coupled to the temperature control module receiving configuration. The provided temperature control module is operatively coupled to the other components of the delivery box cabinet. In particular, the temperature control module is coupled to the other components of the delivery cabinet such that the temperature control module functions as cooling unit for the inside of at least one delivery compartment of the delivery box cabinet. This configuration results in a highly functional, efficient and compact overall implementation for a delivery box cabinet.

### BRIEF DESCRIPTION OF THE DRAWINGS

A more complete appreciation of the present embodiments and many of the attendant advantages thereof will be readily obtained as the same become better understood by reference to the following detailed description when considered in connection with the accompanying drawings, wherein:

FIG. 1 is a perspective front view of a delivery box cabinet according to an exemplary embodiment of the present disclosure;

FIG. 2 is a perspective back view of the delivery box cabinet of FIG. 1;

FIG. 3 is a perspective front view of the delivery box cabinet of FIG. 1 in a partially disassembled state;

FIG. 4 is a perspective partial front view of the partially disassembled delivery box cabinet of FIG. 3;

FIG. 5 is a perspective partial top view of the delivery box cabinet of FIG. 1 in another partially disassembled state;

FIG. 6 is a perspective partial back view of the delivery box cabinet of FIG. 1 in another partially disassembled state; and

FIG. 7 is a perspective partial front view of the delivery box cabinet of FIG. 6.

### DETAILED DESCRIPTION

An exemplary embodiment of the present disclosure will now be described with reference to the accompanying drawings, wherein identical reference numerals designate identical elements throughout the various drawings.

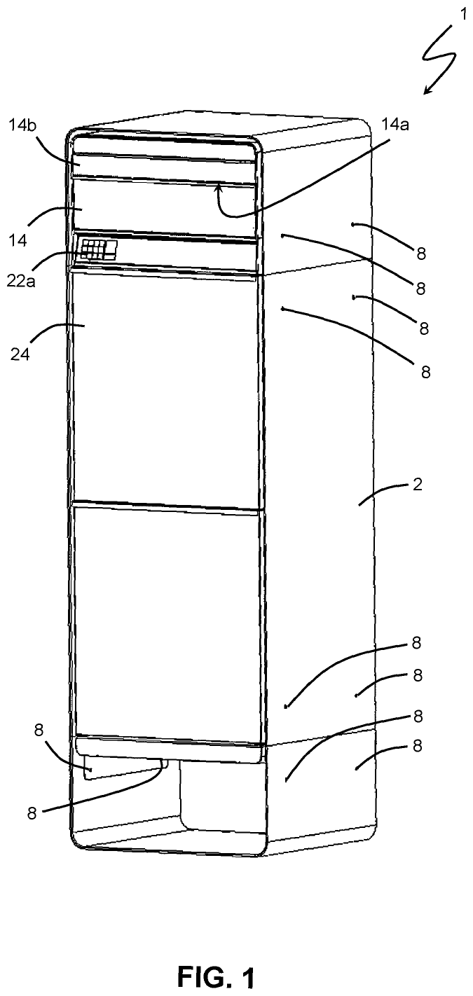

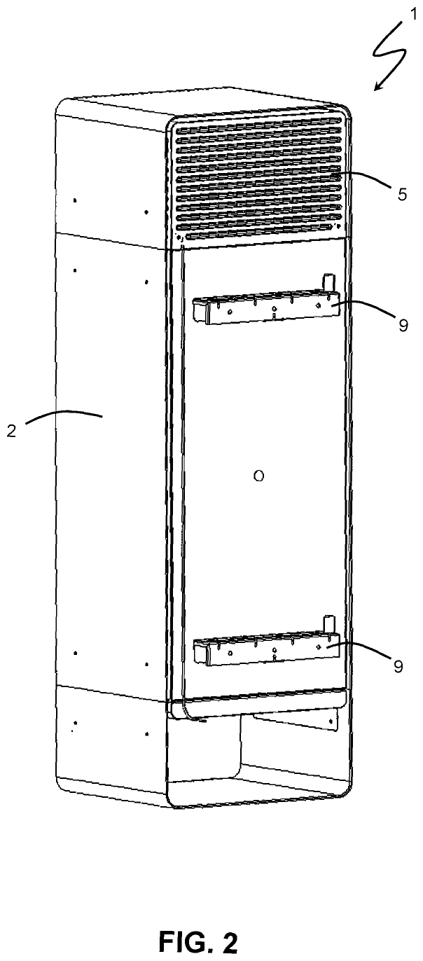

FIG. 1 shows a perspective front view of the exemplary delivery box cabinet 1 according to one embodiment of the present embodiments. FIG. 2 shows a perspective back view of the delivery box cabinet 1.

As can be seen in FIGS. 1 and 2, the delivery box cabinet 1 comprises an outer frame or housing 2 and at least two compartment doors 14 and 24. The at least two compartment doors 14 and 24 are coupled to the outer frame or housing 2 of the delivery box cabinet 1. Each of the two compartment doors 14 and 24 is coupled to the outer frame or housing 2 in a pivotal manner such that each compartment door 14 or 24 can be moved between a closed state and an opened state with respect to the outer frame or housing 2. The compartment doors 14 or 24 can be moved independently of each other.

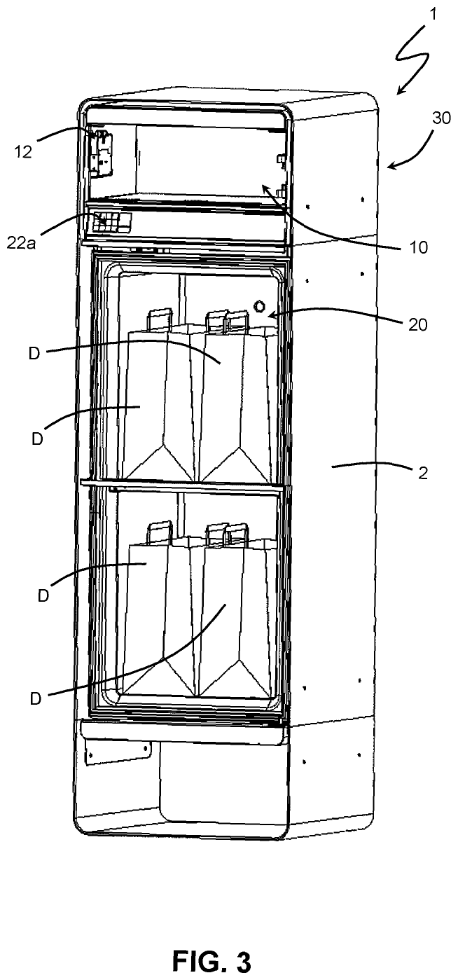

As shown in FIG. 3, in which the compartment doors 14 and 24 have been omitted, the delivery box cabinet 1 comprises a first delivery compartment 10 and a second delivery compartment 20. In the illustrated drawings, the second delivery compartment 20 is filled with deliveries D, here in the form of bags filled with food. The deliveries D and/or the bags are obviously no components of the delivery box cabinet 1 itself. The first delivery compartment 10 is a mailbox compartment 10 configured to receive and store mailings such as letters and/or parcels. The second delivery compartment 20 is a food compartment configured to receive and store deliveries D containing food.

It is to be highlighted that said two delivery compartments 10 and 20 are different form each other and depict individual components of the delivery box cabinet 1. In the following, the first delivery compartment 10 will be referred to as mailbox compartment 10 and the second delivery compartment 20 will be referred to as food compartment 20.

The first compartment door 14 is configured to seal the mailbox compartment 10. Thus, in the following the first compartment door 14 is referred to as mailbox compartment door 14. Here, the mailbox compartment 10 is positioned vertically on top of the food compartment 20 such that commonly quite large and heavy food deliveries can be loaded within the food compartment 20 in an easy and comfortable manner, while at the same time mailings can be loaded to the mailbox compartment 10 in an easy and comfortable manner as well. The second compartment door 24 is configured to seal the food compartment 20. Thus, in the following the second compartment door 24 is referred to as food compartment door 24. The specific configuration of the two compartment doors 14 and 24 and the thereto related components will be discussed below in more detail.

The delivery box cabinet 1 further comprises a temperature control module 30 or temperature control unit 30. The temperature control module 30 is configured to control at least the temperature within the inner of the food compartment 20. Said temperature control module 30 is provided within a temperature control module receiving configuration 4. Here, the temperature control module receiving configuration 4 is configured as receiving section located behind the mailbox compartment 10 on top of the rear side of the food compartment 20. This configuration is space efficient as the mailbox compartment 10 does not need as much space as the food compartment 20 in the depth. Thus, the final configuration is compact while the original functions of the mailbox compartment 10 and of the food compartment 20 are not impaired by the temperature control module 30.

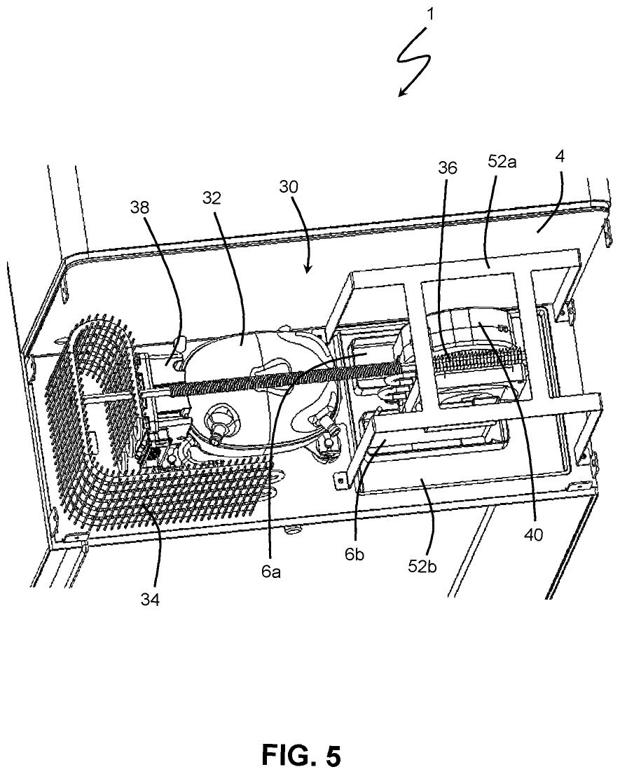

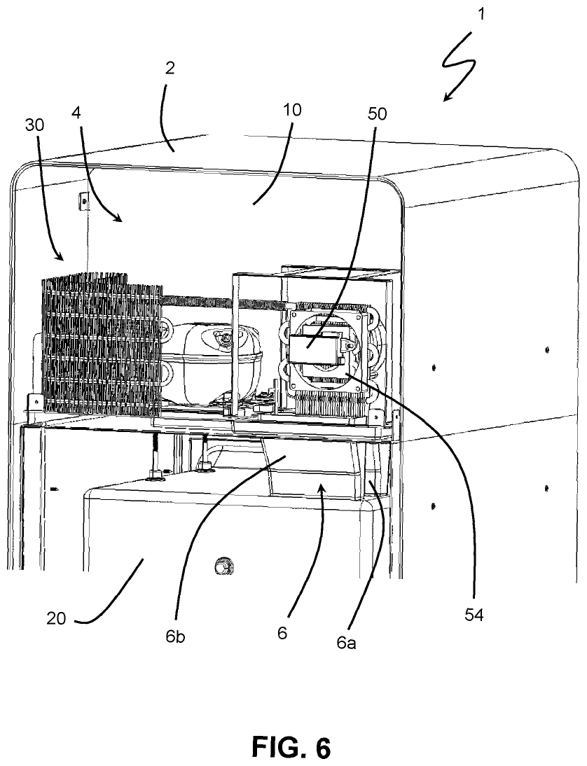

As can be seen in FIG. 2 in view of FIGS. 5 and 6, the temperature control module 30 is enclosed by the frame or housing 2 and a ribbed cover plate 5. The cover plate 5 shields the temperature control module 30 from external influences but allows a temperature exchange between the temperature control module 30 and the environment of the delivery box cabinet 1.

In the illustrated embodiment, the mailbox compartment 10, the food compartment 20 and the temperature control module 30 are provided as distinct modular components which are coupled to each other by suitable fastening means 8, for example screws. In the assembled state of the delivery box compartment 1 the mailbox compartment 10, the food compartment 20 and the temperature control module 30 are enclosed by the common outer frame or housing 2. The outer frame or housing 2 is provided in a weatherproof manner, for example being made of stainless steel or other suitable materials. This allows to set up the delivery box assembly 1 outdoors without the need of providing a further weather protection for the delivery box assembly 1.

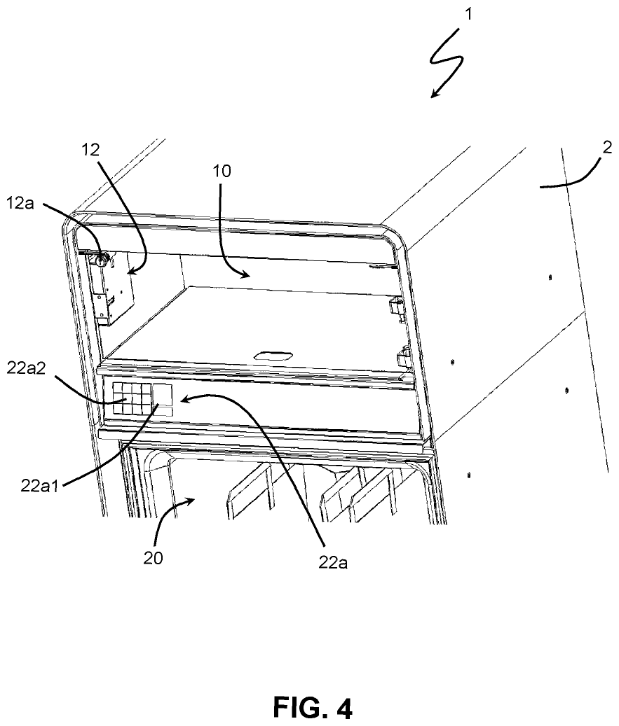

As can be seen in particular in FIG. 4, the delivery box cabinet 1 comprises a mailbox compartment locking unit 12. The mailbox compartment locking unit 12 is configured to lock the mailbox compartment door 14 in the closed state thereof and thus to lock the mailbox compartment 10. Here, the mailbox compartment locking unit 12 is provided in the form of a mechanical lock configured to be locked and unlocked with a physical mailbox compartment locking unit key (not illustrated). The key has to be inserted into a mailbox compartment locking unit keyhole 12a of the mailbox compartment locking unit 12. As such mechanical locking units 12 are well known in the art and the concrete structural and functional configuration thereof will not be described in detail here.

Moreover, the delivery box cabinet 1 comprises a food compartment locking unit 22. The food compartment locking unit 22 is configured to lock the food compartment door 24 in the closed state and thus to lock the food compartment 20. Here, the food compartment locking unit 22 is provided in the form of an electronic lock configured to be locked and unlocked via an electronic user interface 22a. In the illustrated embodiment the electronic user interface 22a is provided in the form of a keypad. The user interface 22a comprises a display section 22al for displaying various information and an input section 22a2 for inputting control commands by the user. As such electronic locking units are well known in the art and the concrete structural and functional configuration thereof will not be described in detail here.

It is to be noted that the two compartment locking units 12 and 22 are provided in such a manner that they can be locked and unlocked separately from each other. In other words, the locking state of the mailbox compartment locking unit 12 is not linked to the locking state of the food compartment locking unit 22 and vice versa.

In the illustrated embodiment, the mailbox compartment door 14 defines a mailing insertion slot 14a. The mailing insertion slot 14a allows access to the interior of the mailbox compartment 10 at least in a limited manner through the mailbox compartment door 14, even when the compartment door 14 is in the closed state. Such a configuration is quite common for mailbox compartment doors 14 and thus will not be described in detail. An insertion flap 14b is configured and coupled to the mailbox compartment door 14 in such a manner that it can be moved between a first position and a second position. In the first position the insertion flap 14b covers the mailing insertion slot 14a. In the second position the insertion flap 14b does not cover the mailing insertion slot 14a. Such a configuration is, at least in principle, well known and is, thus, not described in detail here.

As can be seen in FIG. 4 together with FIG. 1, the mailbox compartment locking unit keyhole 12a is arranged such that in the closed state of the mailbox compartment door 14 it is positioned within the mailing insertion slot 14a and covered by the insertion flap 14b. Thus, the mailbox compartment locking unit keyhole 12a is protected against water and dirt from the environment of the delivery box cabinet 1. This improves longtime performance of the mailbox compartment locking unit 12. To insert the locking unit key into the mailbox compartment locking unit keyhole 12a, the insertion flap 14b has to be moved into its second position.

In the illustrated embodiment, the user interface 22a of the food compartment locking unit 22 is arranged on a tilted surface on the front side of the delivery box cabinet 1 in such a manner that it can be operated by the user independently of the opening state of the mailing compartment door 24. However, the user interface 22a can also be provided in such a manner that it can be operated by a user only from the inside of the mailbox compartment 10. In other words, the electronic user interface 22a can be positioned within the mailbox compartment 10 in such a manner that the mailbox compartment door 14 has to be in the open state to enable a user to operate the user interface 22a and, thus, to control the food compartment locking unit 22. Such a configuration results in more security for the deliveries stored in the food compartment 20.

As can be seen in FIG. 2, the delivery box cabinet 1 of the illustrated embodiment comprises two anchoring components 9 arranged on the back of the delivery box cabinet 1. The anchoring components 9 are configured to anchor the delivery box cabinet 1 to a suitable anchoring structure, for example like a wall of a building. Alternatively, similar anchoring components can be provided on a bottom of the delivery box cabinet 1 or such anchoring components could be omitted completely.

At this point, it is noted that although in the illustrated embodiment only one mailbox compartment door 14 and only one food compartment door 24 are provided on the front side of the delivery box cabinet 1, more than one mailbox compartment door 14 and/or more than one food compartment door 24 can be provided as well. Further compartment doors do not have to be arranged just for further compartments, but they can also be configured to seal the above discussed mailbox compartment 10 or the food compartment 20. In particular, such further compartment doors can be arranged on a back side of the provided delivery compartments 10 and 20 such that the various compartments 10 and 20 can be accessed also from the other side of the delivery box cabinet 1. Such a configuration is of particular advantage in situations in which the delivery box cabinet 1 is not set up in front of a wall of the user's house but, for example, within an aperture in a wall of the house. Thus, the compartments 10 and 20 can be loaded from outside the house, while the compartments 10 and 20 can be emptied from within the house by a user in an easy and comfortable manner. Of course, the additional compartment doors can be provided with further compartment locking units configured to lock each additional compartment door individually. Also, some of the compartment locking units can be operatively coupled to each other or can be integrally formed. A skilled artisan will be able to think of various door configurations.

Although not illustrated explicitly, the delivery box cabinet 1 further comprises a communication and control unit. The communication and control unit is coupled to at least one electrical component of the delivery box cabinet 1. Examples for such electrical components are the food compartment locking unit 22 or the temperature control module 30. Further examples for such electrical components are various sensor units, like for example temperature sensors or laser barriers, or a further provided alarm unit which is configured to launch an alarm in critical situations, for example like damages of some of the components of the delivery box cabinet 1, or in less critical situations, for example like delivery compartments 10 and/or 20 being fully loaded. Here, the communication and control unit is further configured to be coupled to an external device, for example like a smart phone or tablet, and to communicate therewith, in particular in a wireless manner. Alternatively, configurations in which the external device is coupled to the communication and control unit of the delivery box cabinet 1 via a cable and corresponding connectors are possible as well.

In the present embodiment the communication and control unit is configured to obtain several status information about the mailbox compartment 10 and the food compartment 20 and to forward these status information to the external device. The status information include lock state information indicating the current state of the provided compartment locking units 12 or 22, filling state information indicating whether the various delivery compartments 10 and 22 are empty or loaded and temperature information indicating the current temperature within the delivery compartments 10 and 20. For determining such information corresponding sensors units, in particular including laser sensors and/or temperature sensors, are provided within the delivery box cabinet 1. Furthermore, the communication and control unit is configured to receive and to process control information received from the external device and to control at least some of the electrical components coupled to the communication and control unit based on the processed control information. Alternatively, or in addition thereto, the communication and control unit according to the present embodiment can receive control information input by a user in the user interface 22a. Examples for such control information are temperature control information indicating a target temperature for at least one of the delivery compartments 10 and 20, lock control information indicating a desired lock state for at least one of the locking units 12 and 22 and/or alarm control information indicating a desired operation state like armed or disarmed for the provided alarm unit.

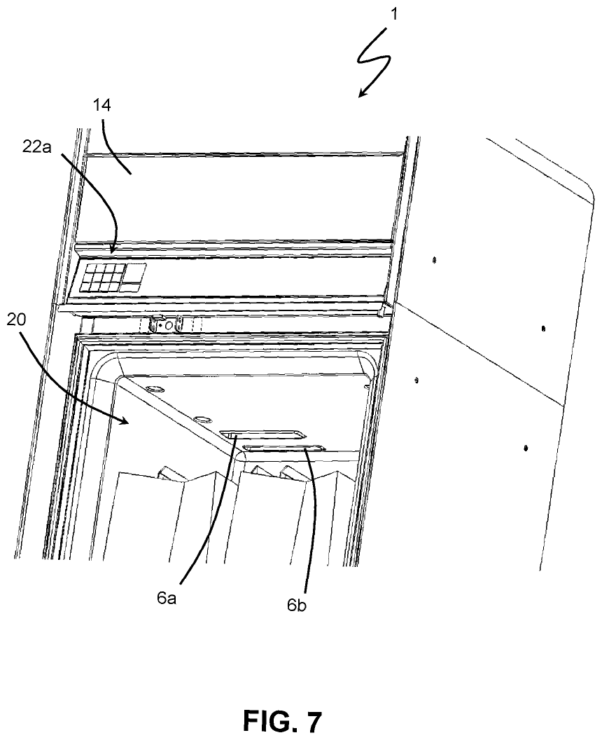

In the following, the specific configuration of the temperature control unit 30 will be described in detail with respect to FIGS. 5 to 7.

In the illustrated embodiment, the temperature control module or unit 30 is configured to serve as cooling unit. However, the temperature control module or unit 30 could be also adapted to be used as heating unit. Moreover, the temperature control module or unit 30 is provided in a compact block-like manner as a, in principle, self-contained component which is installed in the temperature control module receiving configuration 4 of the delivery box cabinet 1. The temperature control module 30 is arranged behind the mailbox compartment 10 on top of the rear side of the food compartment 20. Thus, a very compact overall configuration for the delivery box cabinet 1 is achieved.

The temperature control module 30 comprises a compressor 32, a condenser 34 and an evaporator 36 forming an absorption cooling circuit in a known manner. Furthermore, the temperature control module 30 comprises a controller 50 to control the operation of the temperature control module 30 and in particular of the compressor 32. Moreover, the temperature control module 30 comprises a condenser fan unit 38 and an evaporator fan unit 40. The condenser fan unit 38 is configured to generate a first air flow at the condenser 34 to enhance the temperature exchange capacity at the condenser 34. The evaporator fan unit 40 is configured to generate a second air flow at the evaporator 36 to enhance the temperature exchange capacity at the evaporator 40. The temperature control module 30 further comprises an air flow guiding configuration 52 separating the first air flow from the second air flow. Here, the air flow guiding configuration 52 comprises a housing (not illustrated) enclosing the evaporator 36 and the evaporator fan unit 40. The air flow guiding configuration 42 comprises a frame 52a for supporting the housing and a coupling unit 52b configured to be coupled to an air flow guiding arrangement 6.

In the illustrated embodiment, the air flow guiding arrangement 6 comprises a first air flow guide 6a and a second air flow guide 6b. The first air flow guide 6a and a second air flow guide 6b are provided in such a manner that they connect the inner of the food compartment 20 with the inner of the air flow guiding configuration 52 and thus with the evaporator 36 and the evaporator fan unit 40. The evaporator fan unit 40 is configured to draw air through the first air flow guide 6a from the inner of the food compartment 20 to the evaporator 36 for temperature exchange with the evaporator 36 and then back through the second air flow guide 6b into the food compartment 20. Here, the temperature control module 30 comprises a purification unit 54. The purification unit 54 is positioned within the air flow path between the first air flow guide 6a and the second air flow guide 6b within the air flow guiding configuration 52. The purification unit 54 is configured to purify air traveling through the air flow guiding configuration 42. An example for such a purification unit 54 is a simple air filter or more a complex configuration like an electro filter which can be activated and deactivated via a purification control unit. Here, the controller 50 for the overall temperature control unit 30 is provided on the purification unit 54 resulting in a compact configuration. A purification control unit can be implemented as logic section of the controller 50 to save further space. Further, a purification control unit can be configured to operate the purification unit 54 according to a predetermined operation schedule based, for example, on time information and/or signals received form further provided sensors. The housing of the air flow guiding configuration 52 is formed in a thermally insulating manner to thermally decouple the condenser 34 and the evaporator 36 from each other.

The provided air flow guides 6a and 6b, and possibly further provided air flow guides, can be configured and arranged such that they define various separate temperature zones within the delivery box cabinet 1. As such configurations are quite numerous and a skilled artisan will have no problems in implementing such configurations, further details will not be described.

Finally, it is pointed to the fact that the above described embodiments depict implementations of the embodiments. The corresponding explanations have been provided to explain the features in an illustrative manner. However, the exemplary embodiment should not be read and understood as limiting the accompanying set of claims. A skilled artisan will be able to find various modifications for the above described embodiment without leaving the scope of protection as defined by the accompanying set of claims.

### REFERENCE NUMERALS

1 delivery box cabinet
2 frame and/or housing
4 temperature control module receiving configuration
5 cover plate
6 air flow guiding arrangement
6a first air flow guide
6b second air flow guide
8 fastening means
9 anchoring components
10 first delivery compartment/mailbox compartment
12 mailbox compartment locking unit
12a mailbox compartment locking unit keyhole
14 mailbox compartment door
14a mailing insertion slot
14b insertion flap
20 second delivery compartment/food compartment
22 food compartment locking unit
22a user interface
22a1 display section
22a2 input section
24 food compartment door
30 temperature control unit/temperature control module
32 compressor
34 condenser
36 evaporator
38 condenser fan unit
40 evaporator fan unit
52 air flow guiding configuration
52a frame
52b coupling unit
54 purification unit
D deliveries

1. A temperature control module for a delivery box cabinet, wherein the temperature control module in particular is configured to control the temperature within the inside of at least one delivery compartment of the delivery box cabinet, wherein the temperature control module comprising:
an absorption cooling circuit having a compressor, a condenser and an evaporator,
a controller for controlling the operation of the temperature control module,
the components of the temperature control module are provided in a compact block-like manner, and
the temperature control module is formed self-contained such that it can be installed in a modular manner as a temperature control module in the delivery box cabinet besides the delivery compartments of the delivery box cabinet.

2. The temperature control module of claim 1, wherein
the temperature control module further comprises a condenser fan unit configured to generate a first air flow at the condenser and an evaporator fan unit configured to generate a second air flow at the evaporator to enhance the temperature exchange capacity at the condenser and at the evaporator, respectively.

3. The temperature control module of claim 2, wherein
the temperature control module comprises an air flow guiding configuration configured to separate the first air flow from the second air flow and to guide at least one of the first air flow and the second air flow.

4. The temperature control module of claim 3, wherein
the air flow guiding configuration defines an inlet air flow path to the evaporator and an outlet air flow path away from the evaporator,
wherein the air flow guiding configuration comprises a coupling unit configured to be coupled to an air flow guiding arrangement of the delivery box cabinet.

5. The temperature control module of claim 2, wherein
the temperature control module is configured such that it can be supplemented by a purification unit configured to purify air within the air flow guiding configuration.

6. The temperature control module of claim 1, wherein
the temperature control module comprises a purification unit configured to purify air within the air flow guiding configuration, and a purification control unit for controlling the operation of the purification unit,
wherein in particular the purification control unit is configured to operate the purification unit in accordance with a predetermined operation schedule stored within the purification control unit.

7. The temperature control module of claim 1, wherein
the temperature control module comprises an insulation configuration for separating the various components of the temperature control module from each other and/or from the environment of the temperature control module thermally.

8. The temperature control module of claim 1, wherein
the temperature control module is provided to be used as cooling unit for at least one delivery compartment of the delivery box cabinet.

9. A delivery box cabinet for receiving and storing deliveries, wherein the delivery box cabinet comprises
at least one delivery compartment configured to receive and store deliveries,
the delivery box cabinet further comprises a temperature control module receiving configuration,
wherein the temperature control module receiving configuration is configured such that the temperature control module of any one of the preceding claims can be provided removably in the temperature control module receiving configuration, and
wherein the temperature control module can be coupled to other components of the delivery box cabinet operatively via said temperature regulation module receiving configuration.

10. The delivery box cabinet of claim 9, wherein the delivery box cabinet comprises an air flow guiding arrangement defining at least one air flow path from at least one air flow guiding coupling unit configured to be coupled to a coupling unit of a temperature control module provided in and coupled to the temperature control module receiving configuration of the delivery box module, to the inside of at least one delivery compartment of the delivery box cabinet or vice versa.

11. The delivery box cabinet of claim 10, wherein the air flow guiding arrangement is configured to define several separate air flow guides between the temperature control module provided in and coupled to the temperature control module receiving configuration, and various sections of at least one of the delivery compartments and/or of various separate delivery compartments of the delivery box cabinet to define various different temperature zones within the delivery compartments of the delivery box cabinet.

12. The delivery box cabinet of claim 9, wherein
the delivery box cabinet comprises at least one locking unit configured to lock at least one of the delivery compartments of the delivery box cabinet,
wherein in particular each delivery compartment of the delivery box cabinet comprises at least one individual locking unit.

13. The delivery box cabinet of claim 9, wherein
the delivery box cabinet comprises a communication and control unit, wherein the communication and control unit is configured to exchange information data with at least some of the various components of the delivery box cabinet and/or an external device and/or to control at least some the various components of the delivery box cabinet.

14. The delivery box cabinet of claim 13, wherein
the communication and control unit is configured to be coupled to the controller of a temperature control module provided in and coupled to the temperature control module receiving configuration and to communicate with said controller, and
wherein in particular the communication and control unit is further configured to be coupled wirelessly to an external device.

15. The delivery box cabinet of claim 14, wherein
the communication and control unit is configured to be coupled further to at least one locking unit of the delivery box cabinet as well as to the purification unit of a temperature control module, the communication and control unit is configured to receive information data about a locking state of said locking unit(s) and to process these information data, and
wherein the communication and control unit is configured to control the operation of the purification unit based on said processed information data.

16. The delivery box cabinet of claim 9, wherein
the delivery box cabinet comprises a temperature control module provided in and coupled to the temperature control module receiving configuration,
wherein the provided temperature control module is coupled to the other components of the delivery box cabinet operatively,
wherein in particular, the temperature control module is coupled to the other components of the delivery cabinet such that the temperature control module functions as cooling unit for the inside of at least one delivery compartment of the delivery box cabinet.
